(19) United States
(12) Patent Application Publication
(10) Pub. No.: US 2014/0071632 A1
(43) Pub. Date: Mar. 13, 2014

(54) SEMICONDUCTOR DEVICE, COMMUNICATION DEVICE, AND SEMICONDUCTOR PACKAGE

(71) Applicant: Hitachi Metals, Ltd., Tokyo (JP)

(72) Inventors: Yoshinori SUNAGA, Hitachinaka (JP); Kinya Yamazaki, Hitachi (JP); Hidenori Yonezawa, Hitachi (JP); Yoshiaki Ishigami, Hitachi (JP)

(21) Appl. No.: 13/944,758

(22) Filed: Jul. 17, 2013

(30) Foreign Application Priority Data
Sep. 10, 2012 (JP) 2012-198339

(51) Int. Cl. H01L 23/498

(52) U.S. Cl. CPC H01L 23/49811
USPC 361/728; 257/693

(57) ABSTRACT

A semiconductor device includes a plate shaped semiconductor package substrate, a semiconductor chip mounted on the semiconductor package substrate, a plurality of electrodes formed on a lower surface of the semiconductor package substrate, the plurality of electrodes being electrically connected to a mother board; and a connector formed at an end of the semiconductor package substrate. The connector includes a plurality of terminals to be electrically connected to a plurality of spring terminals of a mating connector which is mated in a parallel direction to the semiconductor package substrate.

The present application is based on Japanese patent application No.2012-198339 filed on Sep. 10, 2012, the entire contents of which are incorporated herein by reference.

### BACKGROUND OF THE INVENTION

1. Field of the Invention

This invention relates to a semiconductor device equipped with a semiconductor chip for use in signal processing of high performance servers, high-speed network devices, etc., a communication device including the semiconductor device and a communication module, and a semiconductor package which constitutes the semiconductor device.

2. Description of the Related Art

Conventionally, as a semiconductor package equipped with a semiconductor chip, there is one equipped with an optical module including an optical fiber for external wiring for high speed signals (see e.g. JP-A-2004-253456 and JP-A-2005-197316).

The semiconductor packages with the optical module described in JP-A-2004-253456 and JP-A-2005-197316 are mounted with a signal processing LSI on a front surface side, and are equipped with an interposer on a back surface side including a solder bump for mounting board connection, and an optical module for the external wiring for the high speed signals. The optical interface module includes an optical fiber for the external wiring for the high speed signals, an optical element for transmitting signals to the optical fiber or receiving signals from the optical fiber, and a connecting pin which is electrically connected to the optical element.

The interposer is formed with a jack on the front surface side to be paired with the connection pin. When the optical module is mated to the interposer in a direction perpendicular to the mounting board, the connecting pin and the jack are mechanically contacted together. Thus, the interposer and the optical module are electrically connected together. That is, the high-speed signals can be transmitted from the interposer to the optical module via the connecting pin but without passing through the electrical wiring on the mounting board.

Refer to JP-A-2004-253456 and JP-A-2005-197316, for example.

### SUMMARY OF THE INVENTION

As disclosed in JP-A-2005-197316 and JP-A-2004-253456 the optical module is mated to the interposer in the direction perpendicular to the mounting board. Thus, it is necessary to provide a space on the interposer during the mating. However, when the heat sink fixed to the mounting board covers the semiconductor chip for heat dissipation of the semiconductor chip, it is not possible to attach or detach the optical module if the heat sink is not detached. Therefore, in some cases, with the heat sink fixed in advance, the optical module cannot be mated to the interposer by routing the optical fiber, causing a restriction on assembling procedure. Further, in the configuration in which the optical module is mated to the interposer in the direction perpendicular to the mounting board, there is a problem that the structure of the jack which is connected to the connection pin of the optical module becomes complicated.

It is an object of the present invention to provide a semiconductor device, a communication device and a semiconductor package that have a simple configuration and allow attachment or detachment of a communication module even when there is no space on a semiconductor chip.

(1) According to one embodiment of the invention, a semiconductor device comprises:

a plate shaped semiconductor package substrate;

a semiconductor chip mounted on the semiconductor package substrate;

a plurality of electrodes formed on a lower surface of the semiconductor package substrate, the plurality of electrodes being electrically connected to a mother board; and

a connector formed at an end of the semiconductor package substrate,

wherein the connector includes a plurality of terminals to be electrically connected to a plurality of spring terminals of a mating connector which is mated in a parallel direction to the semiconductor package substrate.

In the above embodiment (1), the following modifications and changes can be made.

(i) The plurality of terminals are aligned along an end face of the connector.

(ii) The plurality of terminals of the connector are in contact with the plurality of spring terminals by being acted on by a pressing force from the plurality of spring terminals of the mating connector, and

wherein at least a portion of the lower surface at the end of the semiconductor package substrate is formed as a surface to be acted on by a reaction against the pressing force.

(iii) The semiconductor package substrate comprises a wiring layer formed with a wiring pattern for connecting the plurality of terminals and the electrodes respectively of the semiconductor chip, and a support layer for supporting the wiring layer.

(iv) The wiring layer comprises a first wiring layer on the semiconductor chip side and a second wiring layer on the mother board side with the support layer sandwiched between the second wiring layer and the first wiring layer, and

wherein at least one of the plurality of terminals of the connector is connected by the wiring pattern to the electrodes of the semiconductor chip without passing through the second wiring layer.

(2) According to another embodiment of the invention, a communication device comprises:

the semiconductor device according to the above embodiment (1); and

a communication module including a female connector as the mating connector,

wherein the female connector comprises a projecting part abutting on the surface to be acted on to sandwich the connector between the projecting part and the spring terminals.

In the above embodiment (2), the following modifications and changes can be made.

(v) The communication device further comprises:

a socket via which the semiconductor package substrate is connected to the motherboard; and

a frame attached to the motherboard to determine a mating position of the socket and the semiconductor package substrate, and press the semiconductor package substrate against the socket.

(vi) The communication device further comprises a mating portion formed in the frame to be mated with the communication module.

(vii) The communication module comprises an optical element which is optically coupled to an optical fiber and a semiconductor circuit element which is electrically connected to the optical element.

(3) According to another embodiment of the invention, a semiconductor package comprises:

a plate shaped semiconductor package substrate;

a semiconductor chip mounted on the semiconductor package substrate;

a plurality of electrodes formed on a lower surface of the semiconductor package substrate, the plurality of electrodes being electrically connected to a mother board; and

a connector formed at an end of the semiconductor package substrate,

wherein the connector includes a plurality of terminals to be electrically connected to a plurality of spring terminals of a mating connector which is mated in a parallel direction to the semiconductor package substrate.

### POINTS OF THE INVENTION

According to one embodiment of the invention, a semiconductor device is constructed such that connector terminals of a processor (=a semiconductor package substrate with a semiconductor chip mounted thereon) are disposed to project in a direction parallel to a principal surface of a motherboard when the semiconductor package substrate is mounted on the motherboard. Thus, since an optical module is attachable and detachable to and from the semiconductor package substrate in a direction parallel to the motherboard, it is unnecessary to detach a heat sink from the motherboard when attaching or detaching the optical module. Thereby, the replacement of the optical module can be facilitated.

### BRIEF DESCRIPTION OF THE DRAWINGS

The preferred embodiments according to the invention will be explained below referring to the drawings, wherein:

FIG. 1 is a top view showing a communication device in an embodiment of the present invention;

FIG. 2 is an enlarged view showing a connector of a processor;

FIG. 3 is an A-A cross-sectional view of FIG. 1;

FIG. 4 is an enlarged view showing an optical module of FIG. 3;

FIG. 5 is an enlarged view showing a comparative example of the connector of the processor;

FIG. 6 is a top view showing a modification in which a flexible substrate is connected to the processor;

FIGS. 7A and 7B are a cross sectional view and an enlarged top view, respectively, showing a flexible substrate in modification 1;

FIG. 8 is a top view showing a communication device in modification 2 to the embodiment according to the present invention; and

FIGS. 9A and 9B are a cross sectional view and an enlarged top view, respectively, showing a twin coaxial cable in modification 2.

### DETAILED DESCRIPTION OF THE PREFERRED EMBODIMENTS

### Embodiment

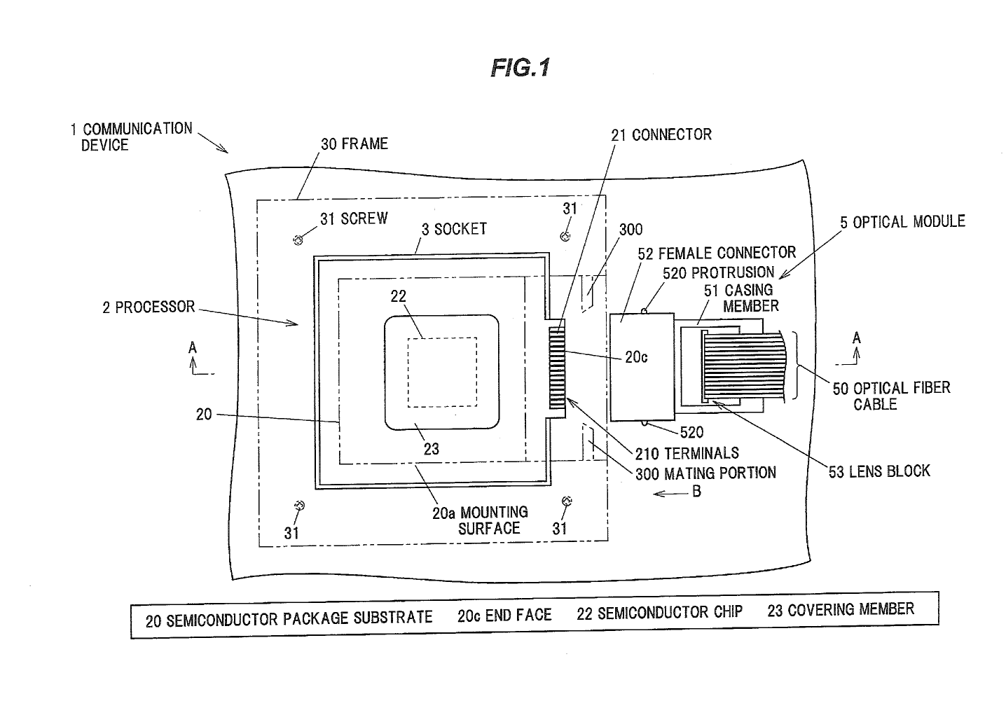

FIG. 1 is a top view showing a communication device 1 in an embodiment of the present invention.

(Configuration of the communication device 1)

The communication device 1 comprises a processor 2 as a semiconductor device, a socket 3, a motherboard 4, an optical module 5 as a communication module, and a frame 30. The processor 2 includes a plate-shaped semiconductor package substrate 20 which is formed with a connector 21 at an end, and a semiconductor chip 22 which is mounted on a mounting surface 20a of the semiconductor package substrate 20. In this embodiment will be described the case the processor 2 is mainly a communication processor which performs communication processing.

The processor 2 is electrically connected to the mother board 4 via the socket 3. The semiconductor package substrate 20 formed in a rectangular shape is formed in such a manner that at one end the connector 21 projects in a direction parallel to the motherboard 4. The plurality of terminals 210 of the connector 21 are aligned on the mounting surface 20a.

The semiconductor package substrate 20 is pressed against the socket 3 by the frame 30 whose outer edge is rectangular. The frame 30 is secured to the motherboard 4 with screws 31 provided at four corners. It is to be noted that a space is formed in a portion corresponding to the connector 21 of the processor 2 in the frame 30 so that a female connector 52 to be described later can be mated with the connector 21 via the space without striking the frame 30. The frame 30 also determines the mating position of the socket 3 and the semiconductor package substrate 20.

The optical module 5 includes the female connector 52, and a casing member 51 for receiving a substrate mounted with circuit components for optical communication, to be described later. In an upper surface side of the casing member 51 is received a lens block 53 to which an optical fiber cable 50 is fixed. The optical fiber cable 50 is drawn out in the opposite direction to the female connector 52 in parallel to the motherboard 4.

The casing member 51 is, for example, 24 mm in entire length along the extending direction of the optical fiber cable 50, and is, for example, 3.6 mm in the thickness direction dimension orthogonal to the extending direction. The depth direction (direction parallel to the alignment of the terminals 210) dimension of the optical module 5 is for example, 23 mm.

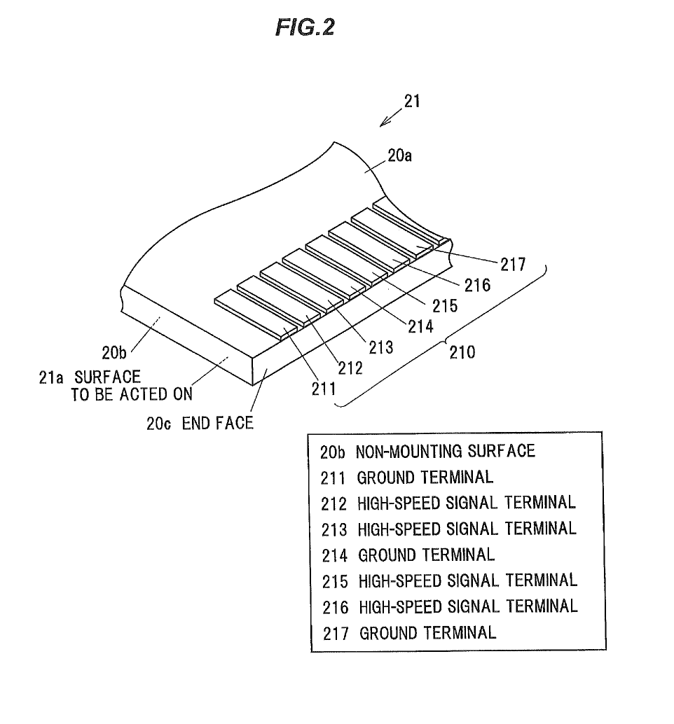

FIG. 2 is an enlarged view showing the connector 21 of the processor 2.

The connector 21 includes a surface 21a to be acted on which will be described later in a non-mounting surface 20b on the back side of the mounting surface 20a. The plurality of terminals 210 are aligned along an end face 20c of the connector 21. The plurality of terminals 210 are aligned in the order of, for example, as shown in FIG. 2, a ground terminal 211, a high speed signal terminal 212, a high-speed signal terminal 213, a ground terminal 214, a high speed signal terminals 215, a high-speed signal terminal 216 and a ground terminal 217. That is, one pair of the high speed signal terminals 212 and 213 are located between the ground terminals 211 and 214, while one pair of the high speed signal terminals 215 and 216 are located between the ground terminals 214 and 217.

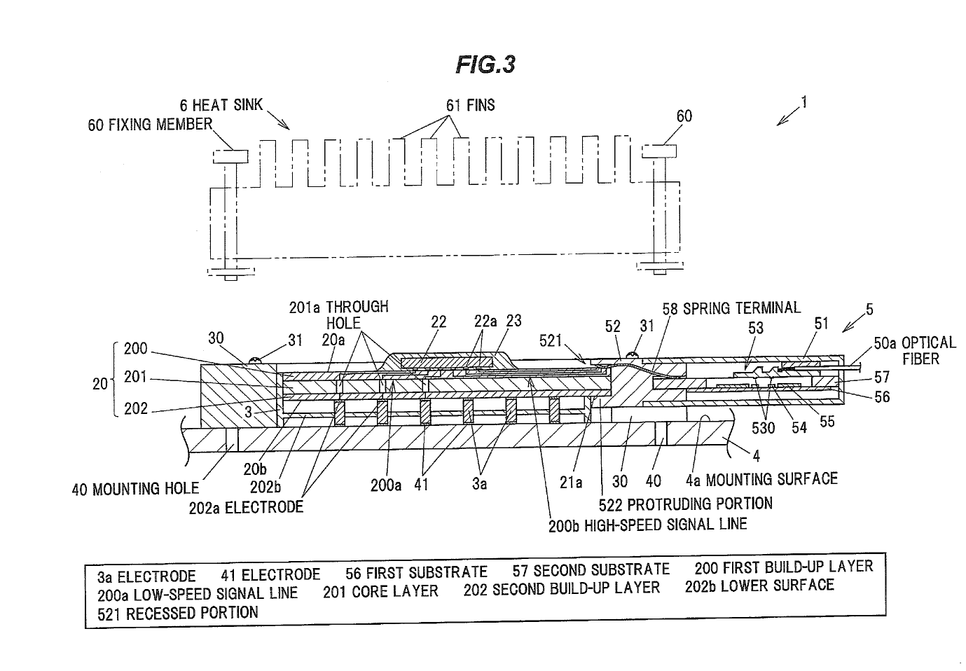

FIG. 3 is an A-A cross-sectional view of FIG. 1. In addition, as a configuration example of the communication device 1, a heat sink 6 is indicated by two-dot chain line.

As shown in FIG. 3, the configuration example of the communication device 1 includes the processor 2, the optical module 5, and the heat sink 6 to absorb the heat produced from each circuit component mounted on the mounting surface 4a of the mother board 4.

(Configuration of the Processor 2)

The processor 2 includes the semiconductor package substrate 20, the semiconductor chip 22 having the plurality of the electrodes 22a, and a covering member 23 as a sealing member for sealing the semiconductor chip 22 with an exposed end formed with the connector 21 of the semiconductor package substrate 20. Incidentally, the covering member 23 may, in some case, not completely cover the semiconductor chip 22, but expose the upper surface (the opposite surface to the surface facing the semiconductor package substrate 20) of the semiconductor chip 22. In this case, the heat dissipation efficiency of the semiconductor chip 22 is improved.

Here, the semiconductor chip is one with a semiconductor element or an integrated circuit (IC) made in a semiconductor substrate such as a silicon substrate by a wafer process, in which the integrated circuit is covered with a passivation film such as a silicon oxide or the like, and a plurality of electrodes of the integrated circuit are exposed at the surface through an opening of the passivation film.

The semiconductor package substrate 20 is formed of a first build-up layer 200 and a second build-up layer 202 as the wiring layer, and a core layer 201 as a support layer for supporting the wiring layer. Some of the plurality of electrodes 22a of the semiconductor chip 22 are connected to a high-speed signal line 200b serving as a wiring pattern which is formed inside the first build-up layer 200, while the others of the plurality of electrodes 22a of the semiconductor chip 22 are connected to a low-speed signal line 200a which is formed inside the first build-up layer 200 and the second build-up layer 202.

The low-speed signal line 200a transmits, for example, a signal such as a control signal, etc., while the high-speed signal line 200b transmits, for example, a relatively high speed signal such as a communication signal or the like in communication through the optical fiber cable 50.

The core layer 201 is formed so as to be sandwiched between the first build-up layer 200 and the second build-up layer 202. The core layer 201 is formed with a plurality of through holes 201a for the low-speed signal line 200a to be passed therethrough. The low-speed signal line 200a passing through the through hole 201a is connected to an electrode 202a formed on a lower surface 202b of the second buildup layer 202.

The electrode 202a is connected to an electrode 41 which is mounted on the mounting surface 4a of the mother board 4 via an electrode 3a of the socket 3. That is, the low-speed signal is transmitted to the motherboard 4 via the socket 3 and the low-speed signal line 200a wired inside the semiconductor package substrate 20 from the semiconductor chip 22. Further, the low-speed signal transmitted to the motherboard 4 from the other circuit components is transmitted from the motherboard 4, to the semiconductor chip 22 via the low-speed signal line 200a wired inside the semiconductor package substrate 20 and the socket 3.

Here, the motherboard is, for example, a main electronic circuit board for constituting an electronic device used in a computer or the like, and is mounted with a CPU (Central Processing Unit) and a chipset, a memory slot, an expansion slot, etc.

The high-speed signal line 200b is connected at one end to the electrodes 22a of the semiconductor chip 22 and is connected at the other end to the terminals 210 of the connector 21. The high-speed signal line 200b connects the terminals 210 of the connector 21 and the electrodes 22a of the semiconductor chip 22 via only the inside of the first build-up layer 200. That is, at least one of the plurality of terminals 210 of the connector 21 is connected to the electrodes 22a of the semiconductor chip 22 by the high-speed signal line 200b without passing through the second build-up layer 202.

By mating of the female connector 52 and the connector 21, the plurality of terminals 210 are connected to a spring terminal 58 which is attached to a second substrate 57 to be described later of the optical module 5. Here, the “spring terminal” means a terminal which is in contact by its elasticity applying a pressing force to the mating terminal (the terminals 210). That is, the high-speed signal is transmitted from the semiconductor chip 22 to the optical module 5 via the spring terminal 58 of the optical module 5 and the high-speed signal wires 200b. Further, the high-speed signal received into the optical module 5 from the other circuit components is transmitted from the second substrate 57 of the optical module 5 to the semiconductor chip 22 via the high-speed signal line 200b and the spring terminal 58.

(Configuration of the Optical Module 5)

As circuit components for optical communications, the optical module 5 includes a pair of optical element arrays 54 in which a plurality of optical elements are arrayed, a pair of semiconductor circuit elements 55 which are electrically connected to the pair of the optical element arrays 54, a first substrate 56 mounted with these circuit components for optical communications, a lens block 53 having lenses 530 to optically couple the plurality of optical elements respectively and the optical fiber cable 50, and a second substrate 57 which is sandwiched between the first substrate 56 and the lens block 53. All of them are received in the casing member 51. A plurality of the spring terminals 58 are attached to the second substrate 57 at one end thereof, while the spring terminals 58 are electrically connected to the terminals 210 of the connector 21 at the other end thereof.

The female connector 52 of the optical module 5 is formed with a protruding portion 522 extending in the direction of mating with the connector 21 of the processor 2. The female connector 52 is mated in a direction parallel to the semiconductor package substrate 20 and the connector 21, and the connector 21 of the semiconductor package substrate 20 is inserted into a recessed portion 521 formed by the protruding portion 522. That is, the connector 21 is sandwiched between the protruding portion 522 and the spring terminals 58 of the female connector 52. At this point, the plurality of terminals 210 are in contact with the spring terminals 58 by being acted on by the pressing force from the spring terminals 58. Further, the non-mounting surface 20b on the back side of the connector 21 to the mounting surface 20a is formed with a surface 21a to be acted on by a reaction against the pressing force from the spring terminals 58, and the protruding portion 522 is in contact with the surface 21a to be acted on.

The processor 2 and the socket 3 are arranged so as to be sandwiched between the heat sink 6 formed with a plurality of fins 61 and the motherboard 4. By fixing a fixing member 60 provided on the heat sink 6 to a mounting hole 40 formed on the mother board 4, the heat sink 6 is attached to the motherboard 4. At this point, the covering member 23 of the processor 2 and the heat sink 6 are in contact with each other, and absorb heat emitted from the semiconductor chip 22.

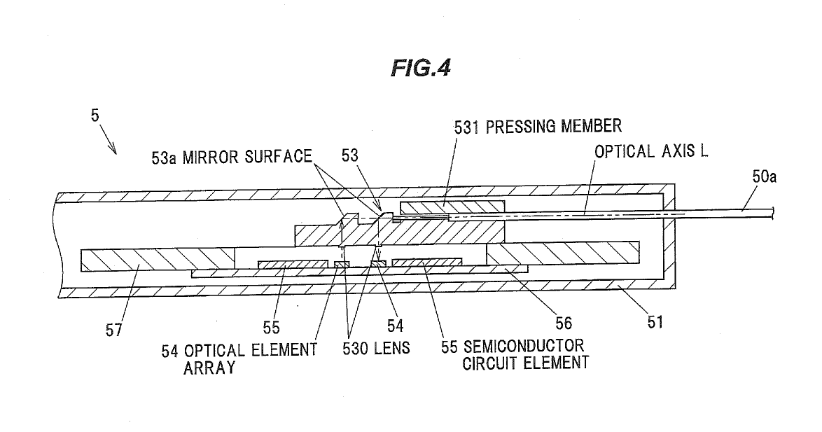

FIG. 4 is an enlarged view showing an optical module of FIG. 3.

(Mechanism of Optical Communications)

The optical elements are an element that converts electrical energy to light, or converts light to electrical energy. As the former light-emitting element, there are listed for example a laser diode, a VCSEL (Vertical Cavity Surface Emitting LASER), and the like. Further, as the latter light receiving element, there are listed for example, a photodiode and the like. The optical elements are configured to emit or receive light to or in the lens block 53.

When the optical elements are an element for converting electric energy to light, the semiconductor circuit elements 55 are a driver IC for driving the optical elements based on an electric signal inputted from the motherboard 4 side. Further, when the optical elements are an element that converts light which the optical elements receive into electric energy, the semiconductor circuit elements 55 are a preamplifier IC that amplifies an electrical signal input from the optical elements and outputs it to the other electronic circuit side.

Incidentally, in this embodiment, one optical element array 54 is a light emitting element, while the other optical element array 54 is a light-receiving element. Therefore, for the semiconductor circuit elements 55, one semiconductor circuit element 55 is a driver IC, while the other semiconductor circuit element 55 is a preamplifier IC.

The lens block 53 is formed with a plurality of lenses 530 which are arranged opposite the optical element arrays 54. The light (optical axis L) emitted from the optical elements of the optical element arrays 54 is condensed by the lenses 530, is reflected off a mirror surface 53a of the lens block 53, and is received in a core of the optical fiber 50a. Further, the light (optical axis L) emitted from the core of the optical fiber 50a is reflected by the mirror surface 53a, is condensed by the lenses 530, and is received in the optical elements. Incidentally, the optical fiber 50a is pressed against the lens block 53 by a pressing member 531.

(Method for Attaching and Detaching the Optical Module 5)

Here, a method for attaching and detaching the optical module 5 and the processor 2 will be explained. To mount the optical module 5 to the connector 21 of the semiconductor package substrate 20, the female connector 52 of the optical module 5 is opposed to the position of the connector 21 of the semiconductor package substrate 20, and is inserted in the arrow B direction in FIG. 1 parallel to the motherboard 4. When the female connector 52 and the connector 21 are mated together, the mating portion 300 which is formed in the frame 30 engages with a protrusion 520 of the female connector 52. That is, by the mating portion 300 engaging the protrusion 520 of the female connector 52, the female connector 52 and the connector 21 are securely mated together. When the optical module 5 is detached from the processor 2, the optical module 5 is pulled out in the opposite direction to the arrow B in FIG. 1.

(Operation of the Communication Device 1)

Next, the operation of the communication device 1 will be described together with the flow of signals. Low-speed signals which are output as a parallel signal from each peripheral device that is mounted on the motherboard 4 are input from the motherboard 4, and via the low-speed signal line 200a, and to the semiconductor chip 22. The individual low-speed signals are converted to high-speed signals within the semiconductor chip 22, and are serially transmitted via the high-speed signal line 200b to the optical module 5. The high-speed signals on the other hand which are output as serial signals from the optical module 5 are input to the semiconductor chip 22 via the high-speed signal line 200b. The high-speed signals input are converted to low-speed signals in the semiconductor chip 22, and are output as parallel signals via the low-speed signal line 200a to the individual peripheral devices.

### Effects of the Embodiment

The embodiment described above has the following effects.

(1) The connector 21 of the processor 2 is mated in such a manner as to be sandwiched by the female connector 52 of the optical module 5. Therefore, the optical module 5 can be inserted or detached along the mating direction. That is, since the optical module 5 is attachable and detachable in a direction parallel to the motherboard 4, the need to detach the heat sink 6 from the motherboard 4 when attaching or detaching is eliminated, and the replacement of the optical module 5 is facilitated.

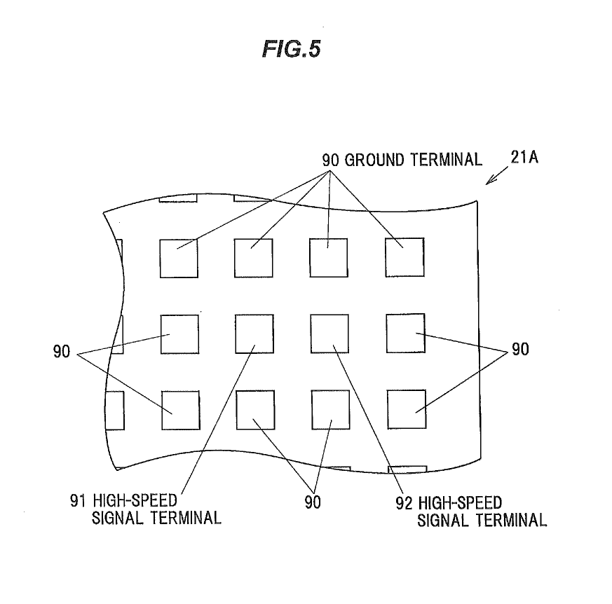

(2) By the plurality of terminals 210 of the connector 21 being aligned along the end of the semiconductor package substrate 20, it is possible to increase the ratio of the number of terminals used for high-speed signal transmission. This will be explained with reference to a comparative example of FIG. 5.

FIG. 5 is an enlarged view showing a comparative example of the connector of the processor. In the connector 21A in the comparative example, plural terminals are arranged in a grid. In this case, the one pair of high speed signal terminals 91 and 92 are surrounded by ten ground terminals 90. When using high-speed signals, in order to reduce the influence on other signals, it is necessary to surround the high speed signal terminals with the ground terminals.

On the other hand, the plural terminals 210 in the embodiment are aligned along the end face 20c of the connector 21. In this case, for the one pair of high speed signal terminals, the one pair of high speed signal terminals may be sandwiched from both ends by the two ground terminals. Therefore, the proportion of the number of high-speed signals in the total number of signals is greater when the terminals are aligned than when arrayed two-dimensionally. This allows good high-frequency characteristics, and high wiring density with enhanced reliability of high speed signal transmission.

(3) Since the high-speed signal line 200b connects the terminals 210 of the connector 21 and the electrodes 22a of the semiconductor chip 22 without passing through the second build-up layer 202, the transmission of the communication signals and the like is not required to pass through the support layer 21 and the second build-up layer 202, and the motherboard 4 and the other circuit components and so on. Therefore, it is possible to shorten the wiring distance between the optical module 5 and semiconductor chip 22, and reduce the transmission loss.

(4) When the socket 3 and the semiconductor package substrate 20 are mated together, it is possible to determine uniquely the mating position of the socket 3 and the semiconductor package substrate 20 by the frame 30 attached to the four corners of the socket 3. Further, by tightening the screws 31 to the frame 30, the semiconductor package substrate 20 is pressed against the socket 3. Thus, the contact between the electrodes 3a of the socket 3 and the electrode 202a of the semiconductor package substrate 20 is ensured and the electrical contact failure is lessened.

(5) By the mating portion 300 of the frame 30 engaging with the protrusion 520 of the female connector 52 of the optical module 5, it is possible to prevent the optical module 5 from slipping off the processor 2.

Further, the communication device 1 in the embodiment may also be implemented by modifying, for example, as follows.

(Modification 1)

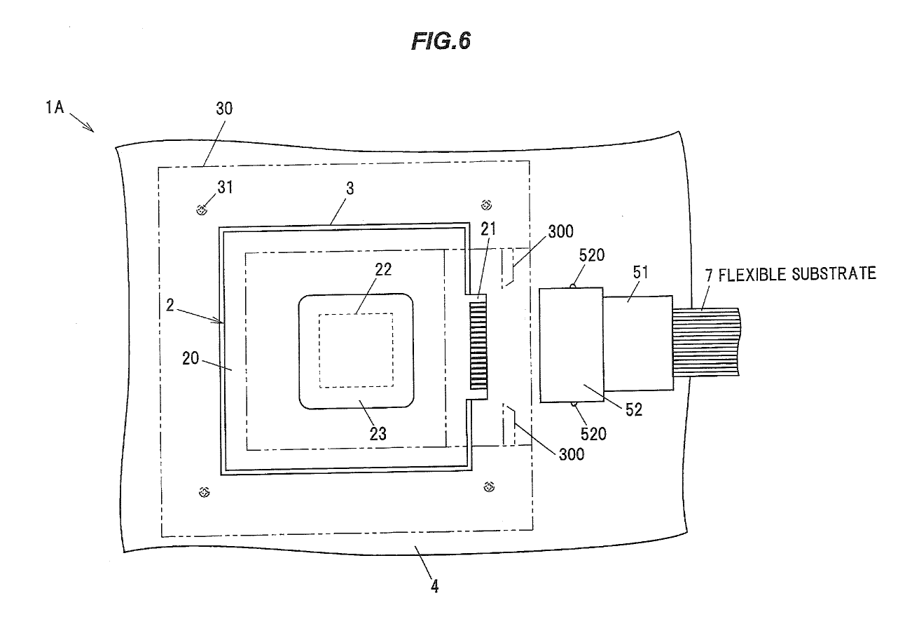

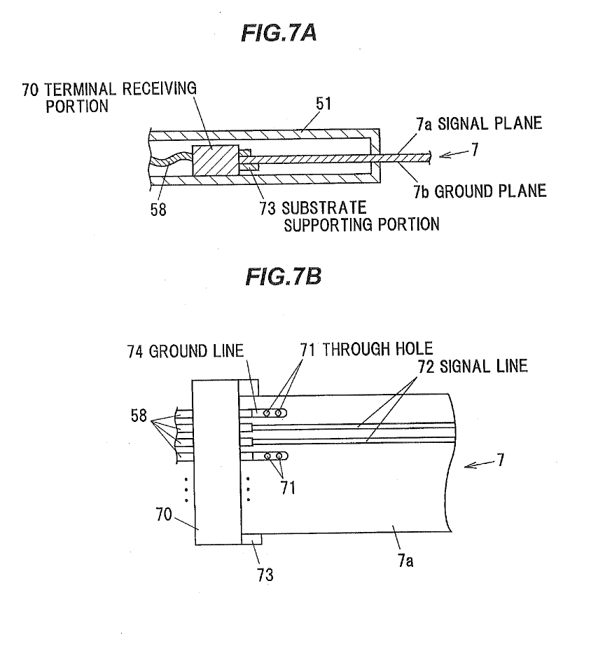

FIG. 6 is a top view showing a communication device 1A in modification 1 to the embodiment of the present invention. FIGS. 7A and 7B are a cross sectional view and an enlarged top view, respectively, showing a flexible substrate 7 in modification 1.

As shown in FIGS. 6 and 7A and 7B, the flexible substrate 7 may, in place of the optical module 5, be connected to the processor 2 via the female connector 52. As shown in FIG. 7A, the flexible substrate 7 includes a signal plane 7a formed with a plurality of signal lines 72 and a ground line 74, and a ground plane 7b formed with a ground pattern not shown on the back side to the signal plane 7a. Further, the flexible substrate 7 is attached with a terminal receiving portion 70 at one end thereof provided with a plurality of the spring terminals 58 connected with the plurality of signal lines 72 or the ground line 74, and is supported by a substrate support member 73. A portion of the flexible substrate 7, the terminal receiving portion 70 and the substrate support portion 73 are received together in the casing member 51.

As shown in FIG. 7B, the plurality of signal lines 72 are wired in the direction parallel to the mating direction of the female connector 52 and the connector 21. The signal lines 72 are connected to the spring terminals 58 at one end thereof and to other electronic components not shown at the other end thereof The ground line 74 is connected to the spring terminals 58 at one end thereof and is connected to the ground pattern of the ground plane 7b by a through hole 71 formed in the flexible substrate 7.

This modification 1 also has effects similar to the effects (1) to (5) described in the above embodiment.

(Modification 2)

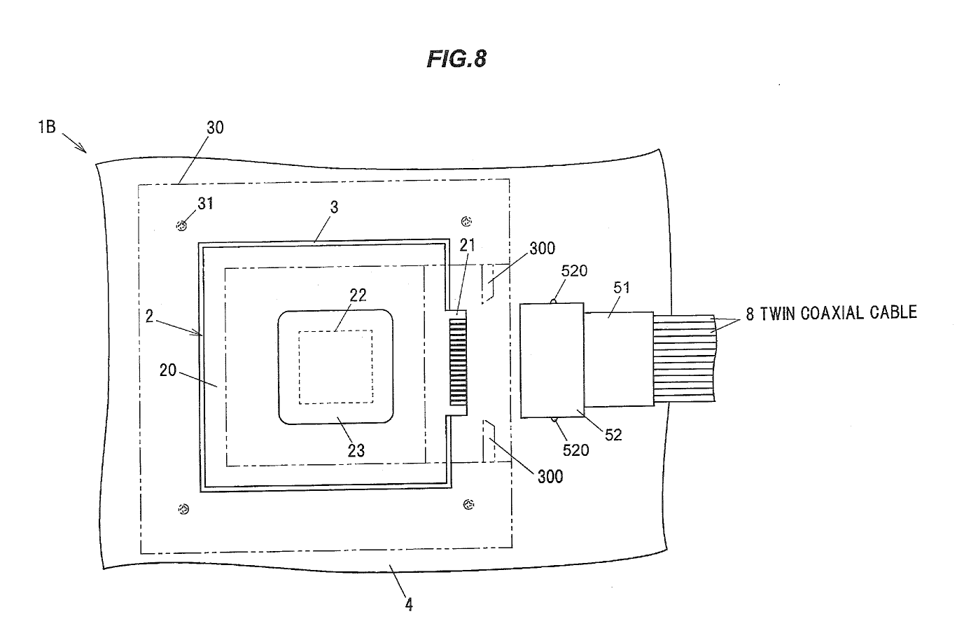

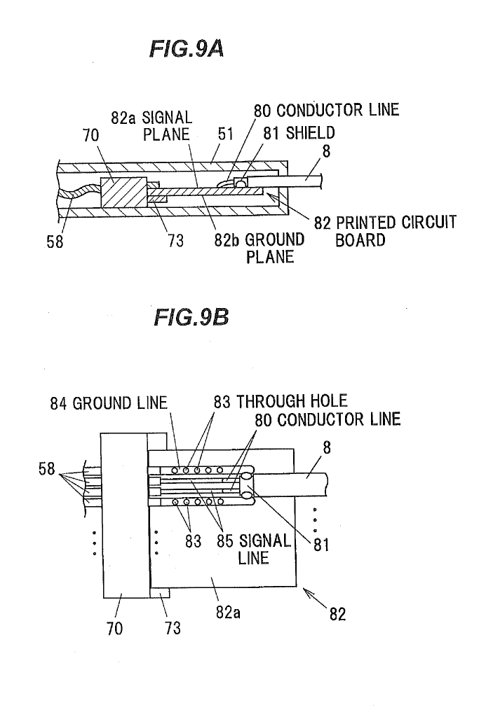

FIG. 8 is a top view showing a communication device 1B in modification 2 to the embodiment according to the present invention. FIGS. 9A and 9B are a cross sectional view and an enlarged top view, respectively, showing a twin coaxial cable 8 in modification 2.

As shown in FIGS. 8 and 9A and 9B, may, in place of the optical module 5, be connected to the processor 2 via a printed circuit board 82. As shown in FIG. 9A, the printed circuit board 82 includes a signal plane 82a wired with a plurality of signal lines 84, and a ground plane 82b formed with a ground pattern not shown on the back side to the signal plane 82a. Further, as with the flexible substrate 7, the printed circuit board 82 is attached with the terminal receiving portion 70 provided with a plurality of the spring terminals 58, and is supported by the substrate support member 73. The printed circuit board 82, the terminal receiving portion 70 and the substrate support portion 73 are received together in the casing member 51.

A plurality of the twin coaxial cables 8 are received in the casing member 51 at one end thereof, and a pair of conductor lines 80 are bared in the inside of the casing member 51. The conductor lines 80 are connected to the spring terminals 58 at one end thereof, and are connected to the ground pattern of the ground plane 82b by a through hole 83 formed in the printed board 82. Also, the ground line 84 is soldered to a shield 81 of the twin coaxial cables 8 at the other end thereof. With the connector 21 of the semiconductor package substrate 20 being mated to the female connector 52, the twin coaxial cables 8 extend in the direction parallel to the motherboard 4.

This modification 2 also has effects similar to the effects (1) to (5) described in the above embodiment.

Although the embodiment of the present invention has been described above, the embodiment described above is not intended to limit the invention in the appended claims. It should also be noted that not all the combinations of the features described in the above embodiment are essential to the means for solving the problems of the invention. For example, in the embodiment, the wiring pattern for connecting between the terminals 210 of the connector 21 and the semiconductor chip 22 is the high-speed signal line 200b, but may be applied to the low-speed signal line 200a.

Further, the connector 21 of the semiconductor package substrate 20 may be formed at each end of the semiconductor package substrate 20, and there is no limit to the number thereof.

Further, the semiconductor package substrate 20 may be not in the rectangular shape, but there is no particular limit to the shape, as long as it is in the plate shape.

Further, as long as the low-speed signal line 200a through the socket 3 is limited to, for example around 5 Gbit/s low-speed signals, the motherboard 4 may use an inexpensive material or structure.

Further, a device other than the modules shown in the embodiment and modifications may be attached according to the shape of the connector 21.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a plate shaped semiconductor package substrate;
a semiconductor chip mounted on the semiconductor package substrate;
a plurality of electrodes formed on a lower surface of the semiconductor package substrate, the plurality of electrodes being electrically connected to a mother board; and
a connector formed at an end of the semiconductor package substrate,
wherein the connector includes a plurality of terminals to be electrically connected to a plurality of spring terminals of a mating connector which is mated in a parallel direction to the semiconductor package substrate.

2. The semiconductor device according to claim 1, wherein the plurality of terminals are aligned along an end face of the connector.

3. The semiconductor device according to claim 1, wherein the plurality of terminals of the connector are in contact with the plurality of spring terminals by being acted on by a pressing force from the plurality of spring terminals of the mating connector, and
wherein at least a portion of the lower surface at the end of the semiconductor package substrate is formed as a surface to be acted on by a reaction against the pressing force.

4. The semiconductor device according to claim 1, wherein the semiconductor package substrate comprises a wiring layer formed with a wiring pattern for connecting the plurality of terminals and the electrodes respectively of the semiconductor chip and a support layer for supporting the wiring layer.

5. The semiconductor device according to claim 4, wherein the wiring layer comprises a first wiring layer on the semiconductor chip side and a second wiring layer on the mother board side with the support layer sandwiched between the second wiring layer and the first wiring layer, and
wherein at least one of the plurality of terminals of the connector is connected by the wiring pattern to the electrodes of the semiconductor chip without passing through the second wiring layer.

6. A communication device, comprising:
the semiconductor device according to claim 3; and
a communication module including a female connector as the mating connector,
wherein the female connector includes a projecting part abutting on the surface to be acted on to sandwich the connector between the projecting part and the spring terminals.

7. The communication device according to claim 6, further comprising:
a socket via which the semiconductor package substrate is connected to the motherboard; and
a frame attached to the motherboard to determine a mating position of the socket and the semiconductor package substrate, and press the semiconductor package substrate against the socket.

8. The communication device according to claim 7, further comprising a mating portion formed in the frame to be mated with the communication module.

9. The communication device according to claim 6, wherein the communication module includes an optical element which is optically coupled to an optical fiber, and a semiconductor circuit element which is electrically connected to the optical element.

10. A semiconductor package, comprising:
a plate shaped semiconductor package substrate;
a semiconductor chip mounted on the semiconductor package substrate;
a plurality of electrodes formed on a lower surface of the semiconductor package substrate, the plurality of electrodes being electrically connected to a mother board; and
a connector formed at an end of the semiconductor package substrate, the connector including a plurality of terminals to be electrically connected to a plurality of spring terminals of a mating connector which is mated in a parallel direction to the semiconductor package substrate.
